(19) United States
(12) Patent Application Publication
(10) Pub. No.: US 2005/0092438 A1
(43) Pub. Date: May 5, 2005

(54) Flat panel display manufacturing apparatus

(76) Inventors: Gwang Ho Hur, Yongin-shi (KR); Jun Young Choi, Seoul (KR); Cheol Won Lee, Anyang-shi (KR); Hyun Hwan Ahn, Sungnam-shi (KR); Saeng Hyun Jo, Daejeon (KR); Sung Il Ahn, Yeongi-gun (KR)

Correspondence Address: Paul D. Durkee;Daly, Crowley & Mofford, LLP, Suite 101, 275 Turnpike Street, Canton, MA, 02021-2354, US

(21) Appl. No.: 10/978,797

(22) Filed: Nov. 1, 2004

(30) Foreign Application Priority Data
Nov. 4, 2003 (KR) 2003-77635
Dec. 19, 2003 (KR) 2003-93774

(51) Int. Cl. H01L 21/00

(52) U.S. Cl. 156/345.47; 118/723 E

(57) ABSTRACT

Disclosed herein is a flat panel display manufacturing apparatus that is capable of performing a predetermined process, such as deposition or etching on a substrate under vacuum. The flat panel display manufacturing apparatus comprises a pin supporting member disposed at the outside of the flat panel display manufacturing apparatus. The pin supporting member is connected to a plurality of lift pins, which lift a substrate from a lower substrate or put the substrate on the lower substrate, for driving the lift pins upward or downward at the same time. Consequently, the inside volume of the flat panel display manufacturing apparatus is decreased as compared to the conventional flat panel display manufacturing apparatus, and thus time for carrying out a pumping operation to apply high-vacuum to the inside of the flat panel display manufacturing apparatus is considerably reduced.

### BACKGROUND OF THE INVENTION

1. Field of the Invention

The present invention relates to a flat panel display manufacturing apparatus that is capable of performing a predetermined process, such as deposition or etching on a substrate under vacuum.

2. Description of the Related Art

Generally, flat panel displays (FPD) are display devices having large-sized flat panels, such as liquid crystal displays (LCD), plasma displays (PDP), and organic light-emitting diode displays (OLED). In manufacturing such flat panel displays, a flat panel display manufacturing apparatus, which etches a substrate or deposits a predetermined object on the substrate, is very useful. Such a flat panel display manufacturing apparatus utilizes sputter etching, reactive ion etching, and plasma enhanced chemical vapor deposition to carry out a predetermined process.

The flat panel display manufacturing apparatus, which performs a predetermined process under vacuum, comprises an upper electrode connected to a high-frequency power supply, a lower electrode that supports a substrate while being grounded, and a substrate processing unit, such as a gas-supply system and an exhaust system, that performs a predetermined process on the substrate.

FIG. 1 is a sectional view showing the structure of a conventional flat panel display manufacturing apparatus.

As shown in FIG. 1, the flat panel display manufacturing apparatus 1 comprises an upper electrode 10 and a lower electrode 20. On the lower electrode 20 is disposed a substrate, on which a predetermined process is carried out. Through predetermined positions of the lower electrode 20, specifically, through lift pin through-holes 22 formed at the lower electrode 20 are inserted lift pins 32 to facilitate introduction and discharge of the substrate. The lift pins 32 are provided, in large numbers, in the flat panel display manufacturing apparatus. The plurality of lift pins 32 are connected to a single pin supporting member 34 such that the lift pins 32 can vertically move at the same time. As shown in FIG. 1, the pin supporting member 34 is disposed inside the flat panel display manufacturing apparatus 1. To the lower side of the pin supporting member 34 are connected a plurality of pin supporting member driving shafts 36. The pin supporting member driving shafts 36 are inserted through the lower part of the flat panel display manufacturing apparatus 1 such that the pin supporting member driving shafts 36 can be connected to an external plate 38 disposed outside the flat panel display manufacturing apparatus 1. The external plate is driven by means of a driving unit 40, which is connected to the external plate 38 such that the pin supporting member driving shafts 36 and the pin supporting member 34 can be driven. Consequently, the lift pins 32 are moved vertically.

When the pin supporting member 34 is disposed inside the flat panel display manufacturing apparatus 1 as shown in FIG. 1, the inside volume of the flat panel display manufacturing apparatus 1 is increased corresponding to the height occupied by the pin supporting member 34. Specifically, the inside volume of the flat panel display manufacturing apparatus 1 is increased due to the pin supporting member 34, and accordingly, time for carrying out a pumping operation to apply high-vacuum to the inside of the flat panel display manufacturing apparatus 1 is increased. Consequently, operational efficiency of the flat panel display manufacturing apparatus 1 is deteriorated.

In the flat panel display manufacturing apparatus 1, plasma is generated to perform a predetermined process on the substrate with the result that the inside temperature of the flat panel display manufacturing apparatus 1 is increased. When the pin supporting member 34 is disposed inside the flat panel display manufacturing apparatus 1, the pin supporting member 34 is deformed due to the increased inside temperature of the flat panel display manufacturing apparatus 1. To this end, the thickness of the pin supporting member 34 is increased. However, the increased thickness of the pin supporting member 34 further increases the inside volume of the flat panel display manufacturing apparatus 1. In addition, the thickened pin supporting member 34 is structurally unstable.

Furthermore, it is very difficult to maintain and repair the pin supporting member 34 when the pin supporting member 34 is disposed inside the flat panel display manufacturing apparatus 1. Also, the above-mentioned external plate 38, which is necessary to support the pin supporting member 34, further complicates the structure of the flat panel display manufacturing apparatus 1.

In the conventional flat panel display manufacturing apparatus 1, the lift pins 32 and the pin supporting member 34 are made of aluminum. The surfaces of the lift pins 32 and the pin supporting member 34 are anodized. The lift pins 32, which made of aluminum, are attacked by plasma generated while a predetermined process is carried out with the result that an arcing phenomenon occurs. Consequently, the lift pins 32 are damaged or broken, and resulting particles serve as impurities while the predetermined process is carried out, which negatively affects uniform processing of the substrate.

Also, it is necessary that the lift pins 32 be frequently replaced with new ones, since the lift pins 32 are easily damaged or broken. As a result, the operational efficiency of the flat panel display manufacturing apparatus 1 is deteriorated.

Furthermore, the inner circumferences of the lift pin through-holes 22 may be scratched or damaged by the lift pins 32 while the lift pins 32 are vertically moved through the lift pin through-holes 22 of the lower electrode 20. As a result, the anodized films formed on the inner circumferences of the lift pin though-holes 22 may be damaged.

When the anodized films formed on the inner circumferences of the lift pin though-holes 22 are damaged, the lift pin through-holes 22 are easily attacked by plasma. As a result, impurities are formed.

### SUMMARY OF THE INVENTION

Therefore, the present invention has been made in view of the above problems, and it is an object of the present invention to provide a flat panel display manufacturing apparatus having a pin supporting member disposed at the outside thereof.

It is another object of the present invention to provide a flat panel display manufacturing apparatus having a simplified structure wherein the height of the flat panel display manufacturing apparatus is decreased.

It is another object of the present invention to provide a flat panel display manufacturing apparatus having lifting pins, which are made of insulation materials, whereby the lift pins are prevented from being damaged by the attack of plasma.

It is yet another object of the present invention to provide a flat panel display manufacturing apparatus having lift pin through-holes that are not damaged due to vertical movement of the lift pins.

In accordance with one aspect of the present invention, the above and other objects can be accomplished by the provision of a flat panel display manufacturing apparatus, comprising: an upper electrode, a lower electrode, and a substrate processing unit to perform a predetermined process on a substrate, the upper electrode, the lower electrode, and the substrate processing unit being disposed in the flat panel display manufacturing apparatus, wherein the flat panel display manufacturing apparatus further comprises: a plurality of lift pins inserted through lift pin through-holes formed at predetermined positions of the lower electrode, respectively, the lift pin through-holes being formed vertically through the lower electrode; pin fixing units connected to the lower ends of the lift pins inside the flat panel display manufacturing apparatus for fixing the lift pins, respectively, the pin fixing unit being inserted through the lower part of the flat panel display manufacturing apparatus; sealing units having upper ends connected to the corresponding upper ends of the pin fixing units and lower ends connected to the inner surface of the lower part of the flat panel display manufacturing apparatus such that the sealing units can surround predetermined parts of the pin fixing units, respectively, the sealing units maintaining the vacuum inside of the flat panel display manufacturing apparatus while being vertically expanded and contracted when the pin fixing units are vertically moved; a pin supporting member connected to the lower ends of the pin fixing units below the flat panel display manufacturing apparatus for supporting and fixing the pin fixing units; and a driving unit connected to the pin supporting member for driving the pin supporting member upward or downward.

In accordance with another aspect of the present invention, there is provided a flat panel display manufacturing apparatus, comprising: an upper electrode, a lower electrode, and a substrate processing unit to perform a predetermined process on a substrate, the upper electrode, the lower electrode, and the substrate processing unit being disposed in the flat panel display manufacturing apparatus, wherein the flat panel display manufacturing apparatus further comprises: a plurality of lift pins inserted through first pin through-holes vertically formed through predetermined positions of the lower electrode and second pin through-holes vertically formed through predetermine positions of the lower part of the flat panel display manufacturing apparatus for lifting the substrate from the lower electrode or putting the substrate on the lower electrode; a pin supporting member connected to the lower ends of the lift pins below the flat panel display manufacturing apparatus for supporting and fixing the lift pins; sealing units having upper ends connected to the outer surface of the lower part of the flat panel display manufacturing apparatus around the second pin through-holes and lower ends connected to the pin supporting member around the positions where the lift pins are inserted through the pin supporting member such that the sealing units can surround the lower parts of the lift pins, respectively, the sealing units maintaining the vacuum inside of the flat panel display manufacturing apparatus while being vertically expanded and contracted when the lift pins are vertically moved; and a driving unit connected to the pin supporting member for driving the pin supporting member upward or downward.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a sectional view showing the structure of a pin supporting member mounted in a conventional flat panel display manufacturing apparatus;

FIG. 2 is a sectional view showing the structure of a pin supporting member mounted in a flat panel display manufacturing apparatus according to a first preferred embodiment of the present invention;

FIG. 3 is a sectional view showing the structure of a pin supporting member mounted in a flat panel display manufacturing apparatus according to a second preferred embodiment of the present invention;

FIG. 4 is a sectional view showing the structure of a flat panel display manufacturing apparatus according to a third preferred embodiment of the present invention;

FIG. 5 is an exploded perspective view showing a lift pin according to a preferred embodiment of the present invention;

FIG. 6 is a sectional view of the lift pin shown in FIG. 5;

FIG. 7A is an exploded perspective view showing a lift pin according to another preferred embodiment of the present invention;

FIG. 7B is a sectional view of the lift pin shown in FIG. 7A;

FIG. 8 is a sectional view showing the structure of a lift pin through-hole of the flat panel display manufacturing apparatus according to the third preferred embodiment of the present invention;

FIG. 9 is a perspective view showing the structure of a plug according to the present invention;

FIG. 10 is a sectional view showing the plug according to the present invention mounted in a lower electrode; and

FIG. 11 is a sectional view showing the lift pin and plug according to the present invention mounted in the lower electrode.

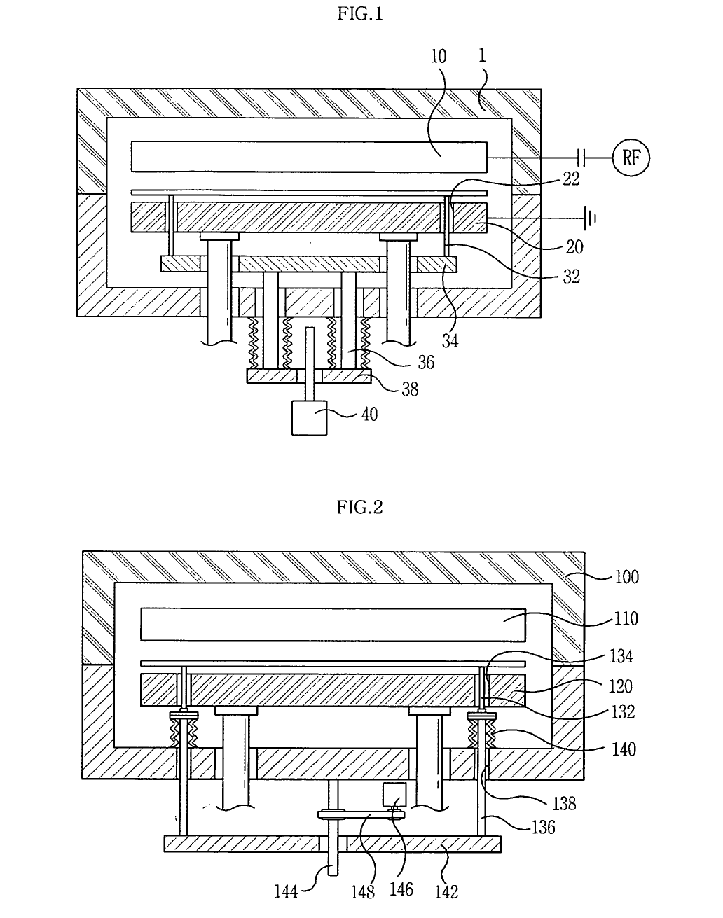

### DESCRIPTION OF THE PREFERRED EMBODIMENTS

Now, preferred embodiments of the present invention will be described in detail with reference to the accompanying drawings.

### Embodiment 1

FIG. 2 is a sectional view showing the structure of a flat panel display manufacturing apparatus 100 according to a first preferred embodiment of the present invention. As shown in FIG. 2, the flat panel display manufacturing apparatus 100 comprises: an upper electrode 110, a lower electrode 120, and a substrate processing unit (not shown). The upper electrode 110, the lower electrode 120, and the substrate processing unit are disposed in the flat panel display manufacturing apparatus 100. The flat panel display manufacturing apparatus 100 further comprises: a plurality of lift pins 132; pin fixing units 136; sealing units 140; a pin supporting member 142; and a driving unit 146.

The lift pins 132 serve to put a substrate on the lower electrode 120 or lift the substrate from the lower electrode 120. The lower electrode 120 is provided at predetermined positions thereof with a plurality of lift pin through-holes 134, which correspond to the lift pins 132, respectively. The lift pins 132 are inserted through the lift pin through-holes 134, respectively. Consequently, the lift pins 132 are vertically moved through the respective lift pin through-holes 134, with the result that the upper ends of the lift pins 132 come into contact with the substrate to vertically move the substrate. Preferably, the lift pins 132 are made of plasma-resistant materials.

The lower ends of the lift pins 132 are connected to the pin fixing units 136, respectively. Specifically, the upper ends of the pin fixing units 136 are securely connected to the lower ends of the corresponding lift pins 132 to fix the lift pins 132. The lower ends of the pin fixing units 136 are inserted through pin fixing unit through-holes 138 formed at predetermined positions of the lower part of the flat panel display manufacturing apparatus 100, and are then connected to the pin supporting member 142. Consequently, the lift pins 132 are connected to the pin supporting member 142 by means of the pin fixing units 136. When the lift pins 132 are damaged or broken, and thus the lift pins 132 are to be replaced or repaired, the lift pins 132 can be separated from the pin fixing units 136. Consequently, replacement or repair of the lift pins 132 can be easily and conveniently carried out.

The upper ends of the sealing units 140 are connected to the upper ends of the pin fixing units 136, respectively, and the lower ends of the sealing units 140 are connected to the inner surface of the lower part of the flat panel display manufacturing apparatus 100, such that the sealing units 140 surround predetermined parts of the pin fixing units 136. Consequently, the pin fixing units 136 can be vertically moved while the inside part of the flat panel display manufacturing apparatus 100 is isolated from the outside part of the flat panel display manufacturing apparatus 100 by means of the sealing units 140. Specifically, the sealing units 140 are disposed such that the sealing units 140 can be vertically expanded and contracted. A seal is formed between the lower ends of the sealing units 140 and the upper ends of the pin fixing unit through-holes 138. Consequently, the sealing units 140 maintain the vacuum inside of the flat panel display manufacturing apparatus 100 while being vertically expanded and contracted when the pin fixing units 136 are vertically moved. Preferably, the sealing units 140 may be bellows modules.

The pin supporting member 142 is formed in the shape of a plate. The lower ends of the pin fixing units 136 are connected to the pin supporting member 142. Specifically, the pin fixing units 136, which are connected to the plurality of lift pins 132, are also connected to the pin supporting member 142 such that the lift pins 132 can be vertically moved at the same time. The plurality of lift pins 132 moves a substrate upward or downward while supporting different positions of the substrate, which comes in contact with the upper ends of the lift pins 132. Consequently, it is necessary that the lift pins 132 be driven to the same height at the same time. To this end, the plurality of lift pins 132 are driven by means of the pin supporting member 142.

Preferably, the pin supporting member 142 is provided at a predetermined position thereof with a driving shaft 144. The driving shaft 144 is connected to the pin supporting member 142 and the driving unit 146 for vertically driving the pin supporting member 142 by means of power supplied from the driving unit 146. Preferably, the driving shaft 144 is formed of a ball screw or a ball spline. This is because fine height adjustment is possible when the driving shaft 144 is formed of the ball screw or the ball spline. Specifically, the driving shaft 144 is provided at the outer surface thereof with a male screw part, and the pin supporting member 142 is provided with a female screw part, which corresponds to the male screw part of the driving shaft 144. Consequently, the pin supporting member 142 is vertically driven when the driving shaft 144 is rotated by means of power supplied from the driving unit 146. In this way, the height of the pin supporting member 142 can be finely adjusted.

The driving unit 146 may be directly connected to the pin supporting member 142 or indirectly connected to the pin supporting member 142 via the driving shaft 144. The driving unit 146 generates and supplies power necessary to vertically drive the pin supporting member 142.

As described above, the driving unit 146 may be connected to the pin supporting member 142 or the driving shaft 144. When the driving unit 146 is directly connected to the pin supporting member 142 or the driving shaft 144, however, it is necessary that the driving unit 146 be connected to the upper part of the driving shaft 144 or the pin supporting member 142. As a result, the height of the flat panel display manufacturing apparatus 100 is increased. The flat panel display manufacturing apparatus 100 is installed in a clean room. Consequently, the height of the clean room is increased when the height of the flat panel display manufacturing apparatus 100 is increased, which increases the installation costs of the flat panel display manufacturing apparatus 100.

For this reason, it is preferable that the driving unit 146 be disposed at the side of the driving shaft 144 while being in parallel with the driving shaft 144, and the driving unit 146 be connected to the driving shaft 144 via a power transmission unit 148 to transmit power to the driving shaft 144 as shown in FIG. 2. Specifically, the driving unit 146 is disposed at the side of the driving shaft 144, not below the driving shaft 144. Consequently, the driving operation can be carried out without increasing the height of the flat panel display manufacturing apparatus 100. Preferably, the power transmission unit 148 is a timing belt.

The operation of the lift pins 132 of the flat panel display manufacturing apparatus 100 according to the first preferred embodiment of the present invention will be described hereinafter in detail.

When the driving unit 146 is operated, power generated from the driving unit 146 is transmitted to the driving shaft 144 via the power transmission unit 148 to rotate the driving shaft 144. As the driving shaft 144 is rotated, the pin supporting member 142 is moved upward or downward by means of the screw engagement between the driving shaft 144 and the pin supporting member 142. As a result, the plurality of pin fixing units 136 and the lift pins 132 connected to the pin supporting member 142 are moved upward or downward at the same time. At this time, the sealing units 140 are vertically expanded or retracted as the pin fixing units 136 are moved upward or downward. Consequently, the vacuum within the flat panel display manufacturing apparatus 100 is maintained although the pin fixing units 136 are vertically moved.

### Embodiment 2

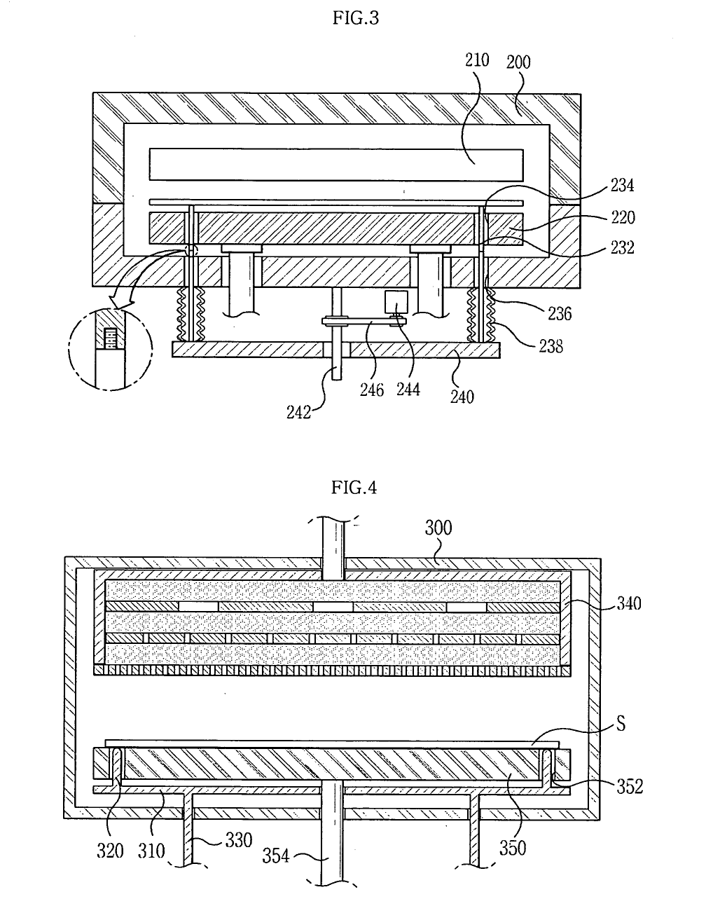

FIG. 3 is a sectional view showing the structure of a flat panel display manufacturing apparatus 200 according to a second preferred embodiment of the present invention. As shown in FIG. 3, the flat panel display manufacturing apparatus 200 comprises: an upper electrode 210, a lower electrode 220, and a substrate processing unit (not shown) The upper electrode 210, the lower electrode 220, and the substrate processing unit are disposed in the flat panel display manufacturing apparatus 200. The flat panel display manufacturing apparatus 200 further comprises: a plurality of lift pins 232; sealing units 238; a pin supporting member 240; and a driving unit 244.

The lift pins 232 serve to put a substrate on the lower electrode 220 or lift the substrate from the lower electrode 220, as in the lift pins 132 of the first preferred embodiment of the present invention. In this embodiment, however, the lift pins 232 are inserted through the lower electrode 220 as well as the lower part of the flat panel display manufacturing apparatus 200, as shown in FIG. 3. Specifically, the lift pins 232 are inserted through first pin through-holes 234 formed through predetermined positions of the lower electrode 220 and second pin through-holes 236 formed through predetermine positions of the lower part of the flat panel display manufacturing apparatus 200. In this case, the length of each of the lift pins 232 is greater than that of each of the lift pins 132 according to the first preferred embodiment of the present invention, as shown in FIG. 3. Consequently, it is difficult to form each of the lift pins 232 out of a single member. Preferably, each of the lift pins 232 is formed out of a plurality of separated members, which are connected to each other.

The sealing units 238 are disposed at the outside of the flat panel display manufacturing apparatus 200. The upper ends of the sealing units 238 are connected to the outer surface of the lower part of the flat panel display manufacturing apparatus 200, and the lower ends of the sealing units 238 are connected to the upper side of the pin supporting member 240. Specifically, the sealing units 238 are connected to the lower part of the flat panel display manufacturing apparatus 200 around the second pin through-holes 236, and the sealing units 238 are connected to the pin supporting member 240 around the positions where the lift pins 232 are inserted through the pin supporting member 240, such that the sealing units 238 can surround the lower parts of the lift pins 232.

In this embodiment of the present invention as described above, the sealing units 238 are disposed at the outside of the flat panel display manufacturing apparatus 200. As a result, it is not necessary to increase the inside height of the flat panel display manufacturing apparatus 200 by the height of the sealing units 238, unlike the first preferred embodiment of the present invention. Consequently, the inside volume of the flat panel display manufacturing apparatus 200 according to the second preferred embodiment of the present invention is less than that of the flat panel display manufacturing apparatus 100 according to the first preferred embodiment of the present invention. Also, the sealing units 238 can be easily and conveniently repaired, since the sealing units 238 are disposed at the outside of the flat panel display manufacturing apparatus 200.

In this embodiment of the present invention, the lower ends of the lift pins 232 are connected to the pin supporting member 240, as in the first preferred embodiment of the present invention. At this time, the plurality of lift pins 232 are connected to the single pin supporting member 240. Consequently, the plurality of lift pins 232 are moved upward or downward at the same time when the pin supporting member 240 is moved upward or downward. Preferably, the pin supporting member 240 is provided at a predetermined position thereof with a driving shaft 242. The driving shaft 242 receives power supplied from the driving unit 244 for vertically driving the pin supporting member 240. Preferably, the driving shaft 242 is formed of a ball screw or a ball spline.

The driving shaft 242 is connected to the driving unit 244. As shown in FIG. 3, the driving unit 244 is indirectly connected to the driving shaft 242 via a power transmission unit 246, although the driving unit 244 may be directly connected to the lower part of the driving shaft 242. In this case, the driving unit 244 is disposed at the side of the driving shaft 242 while being in parallel with the driving shaft 242. As the driving shaft 242 is connected to the driving unit 244 via the power transmission unit 246, the total height of the flat panel display manufacturing apparatus 200 is decreased, as in the first preferred embodiment of the present invention. Preferably, the power transmission unit 246 is a timing belt.

The operation of the flat panel display manufacturing apparatus 200 according to the second preferred embodiment of the present invention will be described hereinafter in detail.

When the driving unit 244 is operated, power generated from the driving unit 244 is transmitted to the driving shaft 242 via the power transmission unit 246 to rotate the driving shaft 242. As the driving shaft 242 is rotated, the pin supporting member 142 is moved upward or downward by means of screw engagement between a male screw part formed at the outer surface of the driving shaft 242 and a female screw part formed at the pin supporting member 240, which corresponds to the male screw part of the driving shaft 242. Consequently, the pin supporting member 240 is vertically driven when the driving shaft 242 is rotated.

As the pin supporting member 240 is driven upward or downward, the plurality of lift pins 232 connected to the pin supporting member 240 are moved upward or downward at the same time. At this time, the sealing units 238 are vertically expanded or retracted as the lift pins 232 are moved upward or downward. Consequently, the vacuum within the flat panel display manufacturing apparatus 200 is maintained although the lift pins 232 are vertically moved.

### Embodiment 3

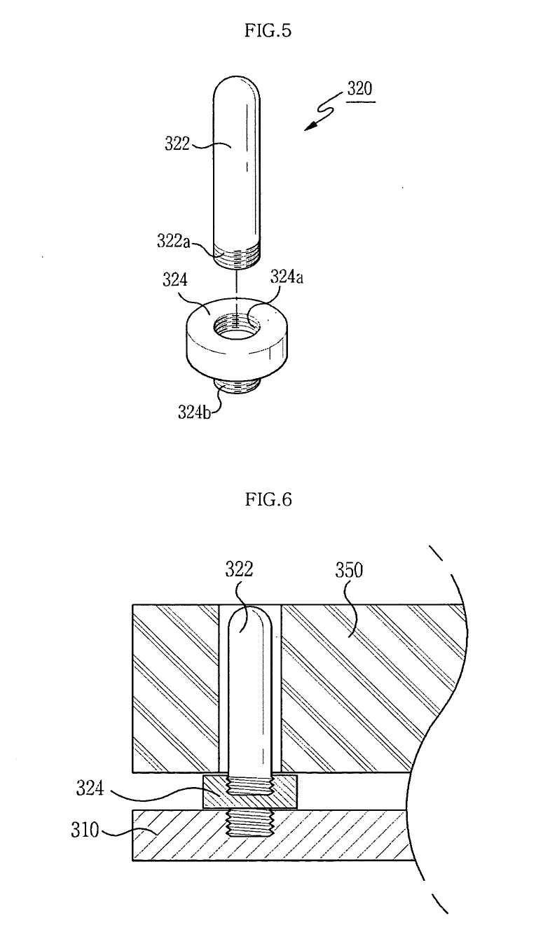

FIG. 4 is a sectional view showing the structure of a flat panel display manufacturing apparatus 300 according to a third preferred embodiment of the present invention. As shown in FIG. 4, the flat panel display manufacturing apparatus 300 has lift pins 320 connected to a pin supporting member 310. As shown in FIG. 5, each of the lift pins 320 comprises a supporting part 322 and a connection part 324.

The supporting part 322 is formed in the shape of an elongated column. The upper end of the supporting part 322 is rounded, and first engaging means 322a is formed at the lower end of the supporting part 322 such that the supporting part 322 can be connected to the connection part 324. Preferably, the first engaging means 322a of the supporting part 322 is formed in the shape of a screw. The supporting part 322 is preferably made of an electric insulation material, such as engineering plastic. More preferably, the supporting part 322 is made of any one selected from the group consisting of ceramic, cerazole, and vespel. It should be noted that the supporting part 322 is made of any one of the above-mentioned insulation materials to avoid attack of plasma generated while a predetermined process is carried out. Since the supporting parts 322 are not damaged by the plasma, the life time of the lift pins 320 is increased, and thus it is not necessary to frequently replace the lift pins 320 with new ones.

The connection part 324 of each of the lift pins 320 is provided at the upper part thereof with second engaging means 324a, which is engaged with the first engaging means 322a formed at the lower end of the supporting part 322. Also, the connection part 324 of each of the lift pins 320 is provided at the lower part thereof with third engaging means 324b, which is engaged with fourth engaging means (not shown) formed at the pin supporting member 310. Preferably, the third engaging means 324b and the fourth engaging means are formed in the shape of screws. The connection part 324 is not necessarily made of an insulation material. Preferably, the connection parts 324 is made of metal having high strength. Also preferably, the connection part 324 has a large diameter such that the connection part 324 can bear attack of plasma for a relatively long time.

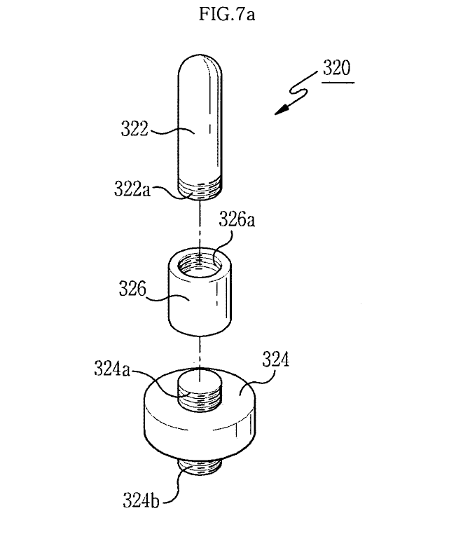

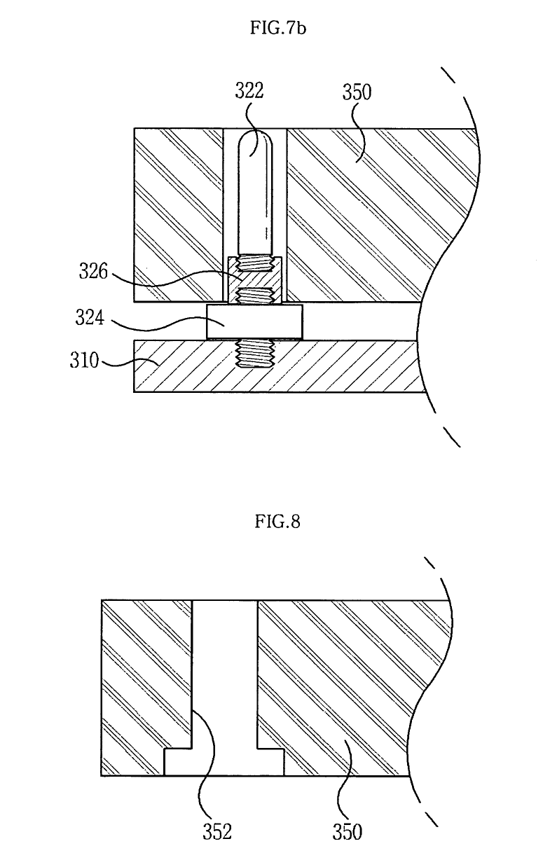

As shown in FIG. 7A, each of the lift pins 320 may further comprise an intermediate part 326. Preferably, the intermediate part 326 is made of an insulation material. More preferably, the intermediate part 326 is made of a material that can be easily processed. In this embodiment of the present invention, the intermediate part 326 is made of the same material as the supporting part 322. The intermediate part 326 is provided at the upper and lower parts thereof with fifth engaging means 326a and sixth engaging means 326b (not shown), respectively, by which the intermediate part 326 can be connected to the supporting part 322 and the connection part 324. Preferably, the fifth and sixth engaging means are formed in the shape of screws. Also, the connection part 324 is provided at the upper part thereof with second engaging means 324a, which is engaged with the sixth engaging means 326b of the intermediate part 326. In this embodiment of the present invention, the second engaging means 324a is formed in the shape of a male screw as shown in FIG. 7A, although the second engaging means 324a may be formed in the shape of a female screw as shown in FIG. 5.

The reason why each of the lift pins 320 has the intermediate part 326 is as follows: When the supporting part 322 is made of an insulation material, the first engaging means 322a may be broken due to low strength of the supporting part 322. If the first engaging means 322a is broken while the first engaging means 322a is engaged with the second engaging means 324a, removal of the first engaging means 322a is very difficult. In the case that each of the lift pins 320 has the intermediate part 326, the first engaging means 322a can be easily removed even when the first engaging means 322a is broken. Also, the intermediate part 326 is made of a material that can be easily processed. Consequently, the position of the intermediate part 326 where the sixth engaging means 326b is formed can be simply changed. Alternatively, various intermediate parts 326 having the sixth engaging means 326b formed at different positions thereof may be previously prepared such that the intermediate part 326 may be replaced, if necessary, to finely adjust the position of each of the lift pins 320.

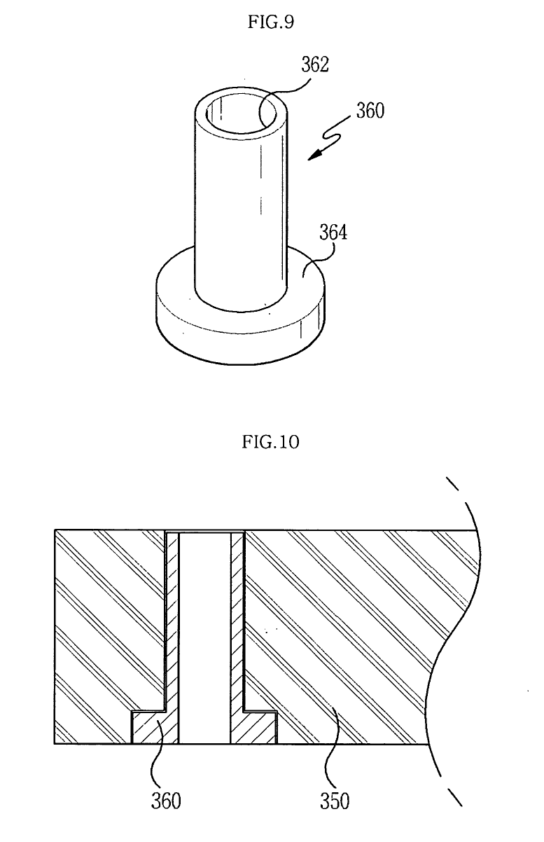

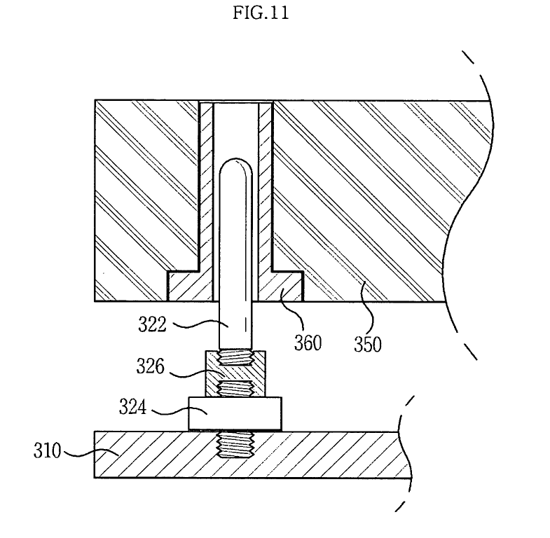

As shown in FIG. 8, lift pin through-holes 352 are formed at a lower electrode 350 disposed in the flat panel display manufacturing apparatus 300 according to the third preferred embodiment of the present invention (one of the lift pin through-holes 352 is shown in FIG. 8). Each of the lift pin through-holes 352 has a first diameter part sufficient for each of the lift pins 320 to be inserted therethrough. Especially, the lower part of each of the lift pin through-holes 352 has a second diameter part, the diameter of which is greater than that of the first diameter part of each of the lift pin through-holes 352. When a lift pin plug 360, which is shown in FIG. 9, is fitted in each of the lift pin through-holes 352, the lift pin plug 360 is prevented from being separated from each of the lift pin through-holes 352 by means of the second diameter part of each of the lift pin through-holes 352.

As shown in FIG. 9, the lift pin plug 360 is formed in the shape of a cylinder having a hollow part 362 defined therein. Also, the lift pin plug 360 is provided at the lower part thereof with a protrusion 364, which corresponds to the second diameter part of each of the lift pin through-holes 352. The lift pin plug 360 is preferably made of an electric insulation material, such as engineering plastic. More preferably, the lift pin plug 360 is made of any one selected from the group consisting of ceramic, cerazole, and vespel.

Now, the operation of the lift pins 320 will be described with reference to FIG. 11. As shown in FIG. 11, the supporting parts 322 are moved upward or downward through the lift pin through-holes 352, respectively. At this time, a substrate S (See FIG. 4) is supported by means of the round upper ends of the supporting parts 322. The reason why the upper ends of the supporting parts 322 are round is to minimize contact between the supporting parts 322 and the substrate S. Also, the lift pin plugs 360 are fitted in the lift pin through-holes 352 for preventing the inner circumferences of the lift pin through-holes 352 from being damaged when the lift pins 320 are vertically moved through the lift pin through-holes 352, respectively.

The lift pins 320 are securely fixed to the pin supporting member 310 in large numbers. Consequently, the plurality of lift pins 320 are moved upward or downward at the same time when the pin supporting member 310 is moved upward or downward by the vertical movement of driving units 330 that drive the pin supporting member 310.

As apparent from the above description, the present invention provides a flat panel display manufacturing apparatus having a pin supporting member, which is disposed at the outside of the flat panel display manufacturing apparatus. Consequently, the present invention has the effect that structural stability of the pin supporting member is improved, and maintenance and repair of the pin supporting member is easily and conveniently carried out.

Also, the inside volume of the flat panel display manufacturing apparatus is decreased, since the pin supporting member is disposed at the outside of the flat panel display manufacturing apparatus. Consequently, time for carrying out a pumping operation to apply high-vacuum to the inside of the flat panel display manufacturing apparatus is considerably reduced.

Furthermore, the thickness of the pin supporting member is reduced, since the pin supporting member is disposed at the outside of the flat panel display manufacturing apparatus. Consequently, mechanical stability of the pin supporting member is improved. Also, it is not necessary to provide an additional external plate at the outside of the flat panel display manufacturing apparatus. Consequently, the structure of the pin supporting member is simplified, and the height of the flat panel display manufacturing apparatus is decreased.

According to the present invention, the lift pins are made of insulation materials. Consequently, the lift pins are not attacked by plasma with the result that the service life of the lift pins is increased. Also, the lift pins can be easily and conveniently replaced with new ones when the lift pins are damaged. In addition, each of the lift pins further comprises an intermediate part. Consequently, the position of each of the lift pins can be finely adjusted.

Furthermore, the lift pin plugs are fitted in the lift pin through-holes formed at the lower electrode. Consequently, the inner circumferences of the lift pin through-holes are not damaged when the lift pins are vertically moved though the corresponding lift pin through-holes. Also, the lift pin plugs can be easily and conveniently replaced when the lift pin plugs are damaged or broken.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A flat panel display manufacturing apparatus, comprising: an upper electrode, a lower electrode, and a substrate processing unit to perform a predetermined process on a substrate, the upper electrode, the lower electrode, and the substrate processing unit being disposed in the flat panel display manufacturing apparatus, wherein the flat panel display manufacturing apparatus further comprises:
a plurality of lift pins inserted through lift pin through-holes formed at predetermined positions of the lower electrode, respectively, the lift pin through-holes being formed vertically through the lower electrode;
pin fixing units connected to the lower ends of the lift pins inside the flat panel display manufacturing apparatus for fixing the lift pins, respectively, the pin fixing unit being inserted through the lower part of the flat panel display manufacturing apparatus;
sealing units having upper ends connected to the corresponding upper ends of the pin fixing units and lower ends connected to the inner surface of the lower part of the flat panel display manufacturing apparatus such that the sealing units can surround predetermined parts of the pin fixing units, respectively, the sealing units maintaining the vacuum inside of the flat panel display manufacturing apparatus while being vertically expanded and contracted when the pin fixing units are vertically moved;
a pin supporting member connected to the lower ends of the pin fixing units below the flat panel display manufacturing apparatus for supporting and fixing the pin fixing units; and
a driving unit connected to the pin supporting member for driving the pin supporting member upward or downward.

2. The apparatus as set forth in claim 1, wherein the sealing units are bellows modules.

3. The apparatus as set forth in claim 1, wherein the pin supporting member is provided at a predetermined position thereof with a driving shaft, the driving shaft being connected to the pin supporting member and the driving unit for vertically driving the pin supporting member by means of power supplied from the driving unit.

4. The apparatus as set forth in claim 3, wherein the driving shaft is formed of a ball screw or a ball spline rotating to vertically move the pin supporting member.

5. The apparatus as set forth in claim 3, wherein the driving unit is disposed at the side of the driving shaft, and the driving unit is connected to the driving shaft via a power transmission unit.

6. The apparatus as set forth in claim 1, wherein each of the lift pins comprises:
a supporting part formed in the shape of an elongated column having a round upper end, the supporting part being made of an insulation material; and
a connection part engaged with the lower end of the supporting part for connecting the supporting part to the pin supporting member.

7. The apparatus as set forth in claim 6, wherein the insulation material is engineering plastic.

8. The apparatus as set forth in claim 6,
wherein each of the lift pins further comprises:
an intermediate part disposed between the supporting part and the connection part for connecting the supporting part and the connection part to each other, the intermediate part being provided at the upper and lower parts thereof with male screws such that the intermediate part can be engaged with the supporting part and the connection part, and
wherein the supporting part is provided at the lower end thereof with a female screw corresponding to the male screw of the intermediate part, and the connection part is provided at the upper end thereof with another female screw corresponding to the male screw of the intermediate part.

9. The apparatus as set forth in claim 8, wherein the intermediate part is made of engineering plastic.

10. The apparatus as set forth in claim 7, wherein the engineering plastic is any one selected from the group consisting of ceramic, cerazole, and vespel.

11. The apparatus as set forth in claim 9, wherein the engineering plastic is any one selected from the group consisting of ceramic, cerazole, and vespel.

12. The apparatus as set forth in claim 1, further comprising:
lift pin plugs fitted in the lift pin through-holes, respectively, wherein each of the lift pin plugs is provided at the center thereof with a hollow part for allowing the corresponding lift pin to be inserted therethrough.

13. The apparatus as set forth in claim 12, wherein the lift pin plugs are made of engineering plastic.

14. A flat panel display manufacturing apparatus, comprising: an upper electrode, a lower electrode, and a substrate processing unit to perform a predetermined process on a substrate, the upper electrode, the lower electrode, and the substrate processing unit being disposed in the flat panel display manufacturing apparatus, wherein the flat panel display manufacturing apparatus further comprises:
a plurality of lift pins inserted through first pin through-holes vertically formed through predetermined positions of the lower electrode and second pin through-holes vertically formed through predetermine positions of the lower part of the flat panel display manufacturing apparatus for lifting the substrate from the lower electrode or putting the substrate on the lower electrode;
a pin supporting member connected to the lower ends of the lift pins below the flat panel display manufacturing apparatus for supporting and fixing the lift pins;
sealing units having upper ends connected to the outer surface of the lower part of the flat panel display manufacturing apparatus around the second pin through-holes and lower ends connected to the pin supporting member around the positions where the lift pins are inserted through the pin supporting member such that the sealing units can surround the lower parts of the lift pins, respectively, the sealing units maintaining the vacuum inside of the flat panel display manufacturing apparatus while being vertically expanded and contracted when the lift pins are vertically moved; and
a driving unit connected to the pin supporting member for driving the pin supporting member upward or downward.

15. The apparatus as set forth in claim 14, wherein each of the lift pins comprises:
a plurality of pieces securely connected to each other.

16. The apparatus as set forth in claim 14, wherein the sealing units are bellows modules.

17. The apparatus as set forth in claim 14, wherein the pin supporting member is provided at a predetermined position thereof with a driving shaft, the driving shaft being connected to the pin supporting member and the driving unit for vertically driving the pin supporting member by means of power supplied from the driving unit.

18. The apparatus as set forth in claim 17, wherein the driving shaft is formed of a ball screw or a ball spline.

19. The apparatus as set forth in claim 17, wherein the driving unit is disposed at the side of the driving shaft, and the driving unit is connected to the driving shaft via a power transmission unit.

20. The apparatus as set forth in claim 14, further comprising:
lift pin plugs fitted in the lift pin through-holes, respectively, wherein each of the lift pin plugs is provided at the center thereof with a hollow part for allowing the corresponding lift pin to be inserted therethrough.

21. The apparatus as set forth in claim 20, wherein the lift pin plugs are made of engineering plastic.
